(19) United States
(12) Patent Application Publication
(10) Pub. No.: US 2001/0009376 A1
(43) Pub. Date: Jul. 26, 2001

(54) Probe arrangement assembly, method of manufacturing probe arrangement assembly, probe mounting method using probe arrangement assembly, and probe mounting apparatus

(76) Inventors: Kiyoshi Takekoshi, Nirasaki-shi (JP); Hisatomi Hosaka, Nirasaki-shi (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(21) Appl. No.: 09/765,423

(22) Filed: Jan. 22, 2001

(30) Foreign Application Priority Data
Jan. 24, 2000 (JP) 2000-013741
Oct. 6, 2000 (JP) 2000-307609

(51) Int. Cl. G01R 31/02

(52) U.S. Cl. 324/754

(57) ABSTRACT

Disclosed is a probe arrangement assembly comprising a conductive foil, a plurality of supporting body-corresponding sections formed in the conductive foil, and contact terminal-corresponding members each fixed to one end of each of the supporting body-corresponding sections. Also disclosed are a method of manufacturing the probe arrangement assembly, as well as a method and an apparatus for mounting a probe to a contactor substrate by using the probe arrangement assembly.

### CROSS-REFERENCE TO RELATED APPLICATIONS

This application is based upon and claims the benefit of priority from the prior Japanese Patent Applications No. 2000-013741, filed Jan. 24, 2000; and No. 2000-307609, filed Oct. 6, 2000, the entire contents of which are incorporated herein by reference.

### BACKGROUND OF THE INVENTION

The present invention relates to a probe arrangement assembly, a method of manufacturing a probe arrangement assembly, a probe mounting method using a probe arrangement assembly, and a probe mounting apparatus.

A probe card is used for inspecting electrical characteristics of an inspecting object, i.e., an object to be inspected, for example, an integrated circuit, hereinafter referred to as “IC chip”, having a large number of memory circuits, logic circuits, etc. formed on a semiconductor wafer, hereinafter referred to simply as “wafer”. The probe card is provided with a plurality of probes arranged to correspond to a plurality of electrode pads of each IC chip. Each probe is electrically connected to the electrode pad of the wafer so as to electrically connect a tester connected to the probe card to the electrode of the IC chip(s). An inspecting signal is exchanged between the tester and the IC chip(s) via the probes.

Recently, the degree of integration of the IC chips is increased and the electrode pads are arranged with a small pitch. In this connection, the probes of the probe card have come to be arranged with a small pitch. A probe card for arranging the probes with a small pitch is proposed in, for example, Japanese Patent Disclosure (Kokai) No. 8-50146 and Japanese Patent Disclosure No. 11-133062. In each of these prior arts, a plurality of probes are collectively formed by utilizing the lithography technology on the surface of a contactor substrate made of, for example, a ceramic material or silicon. The probe has, for example, a contact terminal member that is brought into an electrical contact with the inspecting electrode of the inspecting object and a lead section. The lead section also acts as a supporting member for supporting the contact terminal member with its tip like a cantilever. The contact terminal members are formed on the contactor substrate with an arranging pattern equal to the arranging pattern of the inspecting electrodes of the inspecting object.

### BRIEF SUMMARY OF THE INVENTION

However, where a probe card is manufactured by using the lithography technology, it is necessary to use a photomask adapted for the arranging pattern of the probes every time a different kind of a probe card is manufactured. In addition, even in the case of manufacturing a single kind of probe card, it is necessary to use a plurality of photomasks in order to form a plurality of members forming the probes such as the contact terminal members and the lead sections. In the era of manufacturing a small amount of many kinds of articles, the kinds of the inspecting objects are increased, making it necessary to prepare a probe card adapted for each kind of the inspecting object. Therefore, the number of photomasks used is markedly increased, with the result that much time and expenses are required for preparation of only the photomasks. It follows that the manufacturing cost of the probe card is increased.

An object of the present invention, which has been achieved in an attempt to overcome the above-noted difficulties, is to provide a technology permitting mass production of a probe that can be used commonly for a plurality of different kinds of probe cards.

Another object of the present invention is to provide a method that permits manufacturing a probe card adapted for a small production of many kinds with a low manufacturing cost.

Still another object of the present invention is to provide a probe mounting method and a probe mounting apparatus that permit mounting a single kind of probe to a plurality of different kinds of probe cards differing from each other in the probe arrangement.

According to a first aspect of the present invention, there is provided a probe arrangement assembly used for forming probes, each probe having a supporting body and a contact terminal member fixed to one end of the supporting body, comprising:

a conductive foil having a plurality of sections corresponding to the supporting bodies formed integral with the foil, each of the supporting body-corresponding sections being separable from the conductive foil; and

contact terminal-corresponding members corresponding to the contact terminal members, each of the members being fixed to one end of each of the supporting body-corresponding sections.

In the probe arrangement assembly of the present invention, each of the supporting body-corresponding sections is separable from the conductive foil. It is desirable for the particular construction to be achieved by cutting away the supporting body-corresponding sections from the conductive foil except at least a part of the circumferential edge.

In the probe arrangement assembly of the present invention, it is desirable for at least the tip surface of the contact terminal-corresponding member to be made of a conductive material having a hardness higher than that of the inspecting electrode of the inspecting object.

In the probe arrangement assembly of the present invention, it is desirable for at least the tip portion of the contact terminal-corresponding member to be covered with tungsten carbide.

In the probe arrangement assembly of the present invention, it is desirable for the contact terminal-corresponding member to be made of at least one material selected from nickel and a nickel alloy and for the tip surface of the contact terminal-corresponding member to be covered with tungsten carbide.

Further, it is desirable for the conductive foil to be formed of a metal having a spring force.

Still further, in order to make each of the supporting body-corresponding sections separable from the conductive foil, it is desirable for the probe arrangement assembly of the present invention to be constructed such that a sheet substrate is bonded to the conductive foil and that the peripheral edges of a plurality of supporting body-corresponding sections formed integral with the conductive foil are separated from the conductive foil by slits.

According to a second aspect of the present invention, there is provided a method of manufacturing a probe arrangement assembly used for preparation of a probe having a supporting body formed of a conductive foil and a contact terminal-corresponding member fixed to one end of the supporting body, comprising the steps of:

forming a plurality of supporting body-corresponding sections in a conductive foil, the supporting body-corresponding section being formed separable from the conductive foil;

forming a plurality of contact terminal-corresponding members within a substrate to be etched such that the bottom surface of the contact terminal-corresponding member faces outside the substrate to be etched, the plural contact terminal-corresponding members being arranged to conform with the positions to which the contact terminal-corresponding members are fixed in each supporting body-corresponding section formed in the conductive foil; and

collectively transferring contact terminal-corresponding members formed in the substrate to be etched into the positions to which the contact terminal-corresponding members are fixed in a plurality of supporting body-corresponding sections formed in the conductive foil.

In the manufacturing method of the present invention, it is desirable for the substrate, which is to be etched, to be a silicon substrate, and for each supporting body-corresponding section to be formed separable from the conductive foil by allowing the slits to separate each supporting body-corresponding section from the conductive foil except at least one edge portion.

In the manufacturing method of the present invention, it is desirable for the step of forming a plurality of supporting body-corresponding sections in the conductive foil to comprise the sub-steps of forming a resist film on at least one surface of the conductive foil, forming an opening corresponding to the slit in the resist film, and etching the conductive foil exposed to the opening so as to form the slit in the conductive foil.

In the manufacturing method of the present invention, it is desirable for the step of forming a plurality of contact terminal-corresponding members within a silicon substrate to comprise the sub-steps of forming a resist film on the substrate to be etched, forming openings in the resist film in positions and sizes in which the contact terminal-corresponding members are to be arranged, etching the substrate through the openings so as to form a plurality of recesses of a predetermined shape within the substrate to be etched, and filling a conductive material in the recesses.

In the manufacturing method of the present invention, it is desirable for a sheet substrate to be bonded to the conductive foil and for the peripheral edges of a plurality of the supporting body-corresponding sections formed integral within the conductive foil to be separated from the conductive foil by slits so as to make the supporting body-corresponding sections separable from the conductive foil.

According to a third aspect of the present invention, there is provided a method of manufacturing a probe arrangement assembly used for formation of a probe having a supporting section formed of a conductive foil and a contact terminal-corresponding member fixed to one end of the supporting body, comprising the steps of:

forming a plurality of contact terminal members within a substrate to be etched such that the bottom surface of contact terminal member faces outward;

forming a conductive layer on the substrate to be etched, the bottom surfaces of the plural contact terminal-corresponding members being integrally fixed to each other by the conductive layer;

forming a plurality of slits in the conductive layer so as to form sections corresponding to the plural supporting bodies, the sections corresponding to these supporting bodies including portions to which the contact terminal-corresponding members are fixed and being formed separable from the conductive layer; and

peeling the conductive layer, in which the sections corresponding to the plural supporting bodies are formed, from the substrate to be etched.

In the manufacturing method of the present invention, it is desirable for the substrate, which is to be etched, to be a silicon substrate and for the sections corresponding to the plural supporting bodies, which are separated from the conductive layer by the slits except at least a part of the peripheral edge, to be formed separable from the conductive layer.

In the manufacturing method of the present invention, it is desirable for the step of forming the contact terminal-corresponding members within the silicon substrate to comprise the sub-steps of:

forming a resist film on the silicon substrate;

forming in the resist film openings corresponding to the arrangement and sizes of the sections corresponding to the contact terminal-corresponding members;

etching the silicon substrate through the openings of the resist film so as to form recesses in the silicon substrate; and

filling a conductive material for the contact terminal-corresponding member in the recess.

In the manufacturing method of the present invention, it is desirable for the step of forming a section corresponding to a plurality of the supporting bodies in the conductive layer to comprise the sub-steps of:

forming a resist film on the surface of the conductive film;

forming in the resist film openings corresponding to the arrangement and sizes of the slits; and

etching the conductive film through the opening of the resist film so as to form the slit in the conductive layer.

In the manufacturing method of the present invention, it is desirable for the step of forming a conductive layer on the silicon substrate to be a plating step.

In the manufacturing method of the present invention, it is desirable for the conductive layer to be formed of a conductive metal having a spring force.

In the manufacturing method of the present invention, it is desirable for at least the tip surface of the contact terminal-corresponding member to be covered with a metal layer having a hardness higher than that of the inspecting electrode and excellent in conductivity.

In the manufacturing method of the present invention, it is desirable for a sheet substrate to be bonded to the conductive foil and for the peripheral edges of a plurality of the supporting body-corresponding sections formed integral with the conductive foil to be separated from the conductive foil by slits so as to make the supporting body-corresponding sections separable from the conductive foil.

According to a fourth aspect of the present invention, there is provided a method of mounting a plurality of probes to a contactor substrate by using a probe arrangement assembly used for forming a probe having a plurality of supporting bodies formed of a conductive foil and contact terminal-corresponding members each fixed to one end of each of the supporting bodies, comprising the steps of:

aligning the contactor substrate, which is mounted on a work table, with the probe arrangement assembly;

fixing one of a plurality of supporting body-corresponding sections within the probe arrangement assembly to the contactor substrate; and

separating the fixed supporting body-corresponding section from the probe arrangement assembly.

In the method of the present invention, it is desirable for the step of separating the fixed supporting body-corresponding section from the probe arrangement assembly to comprise separating the supporting body-corresponding section from the conductive foil of the probe arrangement assembly.

In the method of the present invention, it is desirable to use any of the probes.

According to a fifth aspect of the present invention, there is provided an apparatus for mounting a plurality of probes to a contactor substrate by using a probe arrangement assembly used for forming a probe having a plurality of supporting bodies each formed of a conductive foil and contact terminal-corresponding members each fixed to one end of each of supporting bodies, comprising:

a work table having the contactor substrate mounted thereon and movable in X, Y, Z and θ directions;

a supporting body supporting the probe arrangement assembly and movable in at least X and Y directions;

a mechanism for aligning the positions of the contactor substrate and the probe arrangement assembly by moving at least one of the work table and the supporting body;

a mechanism for fixing one of a plurality of supporting body-corresponding sections of the probe arrangement assembly to the contactor substrate; and

a mechanism for separating the fixed supporting body-corresponding section from the probe arrangement assembly.

In the apparatus of the present invention, it is desirable for the mechanism for separating the fixed supporting body-corresponding section from the probe arrangement assembly to include a mechanism for cutting off the peripheral edge of the supporting body-corresponding section from the conductive foil of the probe arrangement assembly.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the preferred embodiments given below, serve to explain the principles of the invention.

FIG. 1 is a cross sectional view showing a main portion of a contactor having probes mounted thereto by a probe mounting method of the present invention;

FIGS. 2A and 2B are plan views showing the contactor shown in FIG. 1, wherein FIG. 2A shows the plane on the probe side, and FIG. 2B shows the plane on the side opposite to the plane of FIG. 2A;

FIG. 3 is a plan view showing the state that the probe arrangement assembly of the present invention is mounted to a frame;

FIGS. 4A and 4B shows in a magnified fashion the probe arrangement assembly shown in FIG. 3, wherein FIG. 4A is a plane view and FIG. 4B is cross sectional view of FIG. 4A;

FIGS. 5A to 5E show the process of forming a supporting body-corresponding portion of the probe on a nickel foil;

FIGS. 6A to 6G show the process of forming the contact terminal-corresponding member on a silicon substrate;

FIG. 7 is a cross sectional view showing how the contact terminal-corresponding member shown in FIGS. 6A to 6G is transferred onto the supporting body-corresponding section shown in FIGS. 5A to 5E;

FIG. 8 is a side view showing the inner region of the probe mounting apparatus according to one embodiment of the present invention;

FIG. 9 shows how the probe-corresponding member is bonded to the contactor substrate and how the probe-corresponding member is cut away from the probe arrangement assembly by using the probe mounting apparatus shown in FIG. 8;

FIG. 10 is a cross sectional view showing a part of the probe arrangement assembly according to another embodiment of the present invention;

FIG. 11 is a plan view showing a probe arrangement assembly according to another embodiment of the present invention;

FIG. 12A is a plan view showing a probe arrangement assembly according to another embodiment of the present invention;

FIG. 12B is a cross sectional view showing the probe arrangement assembly shown in FIG. 12A;

FIG. 13 shows in a magnified fashion a part of the probe arrangement assembly shown in FIG. 12A;

FIGS. 14A and 14B show the inner region of the probe mounting apparatus according to another embodiment of the present invention, wherein FIG. 14A is a plan view and FIG. 14B is a side view; and

FIGS. 15A and 15B show how a probe is mounted to the contactor substrate via the probe mounting apparatus shown in FIGS. 14A and 14B, wherein FIG. 15A is a cross sectional view showing a main portion in a magnified fashion, and FIG. 15B is a cross sectional view showing a main portion of the probe arrangement assembly equipped with a sheet substrate having an opening portion formed therein in a manner to correspond to the contact terminal-corresponding member.

### DETAILED DESCRIPTION OF THE INVENTION

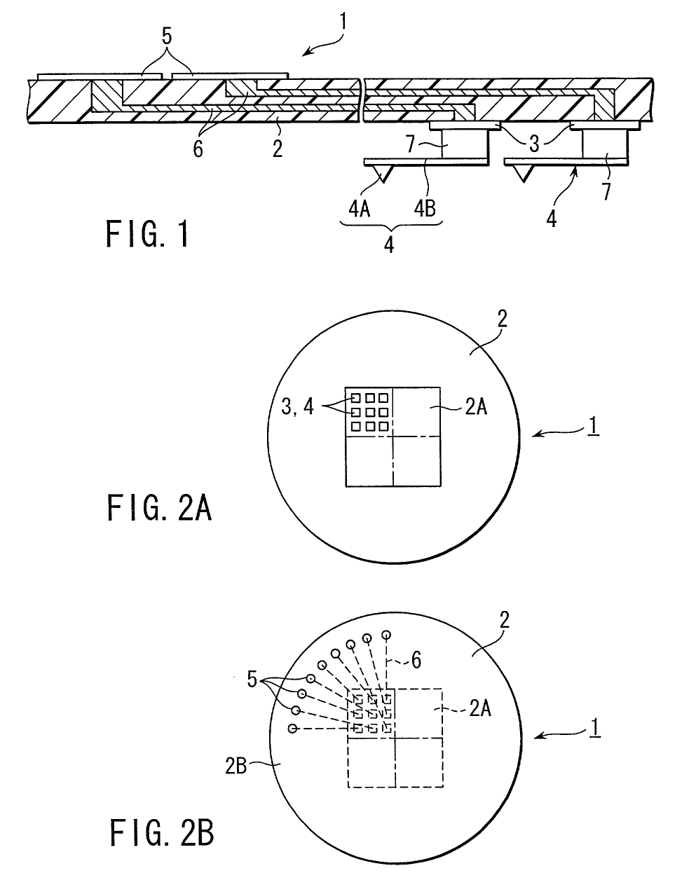

The present invention will now be described on the basis of the embodiments shown in FIGS. 1 to 15B. Specifically, FIG. 1 is a cross sectional view showing in a magnified fashion a contactor manufactured by the probe manufacturing method and the probe mounting method of the present invention. FIGS. 2A and 2B are plan views showing the entire contactor shown in FIG. 1. As shown in FIGS. 1, 2A and 2B, the contactor 1 comprises a contactor substrate 2, e.g., a ceramic substrate, and a plurality of first electrodes 3 arranged on the surface of the contactor substrate 2. It is possible for these first electrodes 3 to be arranged to form a matrix and to be made of a conductive metal such as nickel or a nickel alloy. A plurality of probes 4 are arranged on these electrodes 3. In the inspecting step, each probe 4 is brought into contact with an inspecting electrode pad (not shown) of an inspecting object, i.e., an object to be inspected. A plurality of inspecting objects, e.g., IC chips, can be inspected simultaneously by using the contactor 1. For example, 16 or 32 IC chips can be simultaneously inspected by using the contactor 1. As shown in FIGS. 2A and 2B, the contactor substrate 2 can be formed substantially circular. The probes 4 can be arranged to form a matrix in a rectangular central region 2A on the contactor substrate 2 as shown in, for example, FIG. 2A. Second electrodes 5 are arranged in a peripheral region 2B on the back surface of the contactor electrode 2 as shown in FIG. 2B. These second electrodes 5 can be arranged to form a circular configuration. These first electrodes 3 and second electrodes 5 are electrically connected to each other via a wiring 6 arranged within the contactor substrate 2, as shown in FIG. 1.

As shown in FIG. 1, the probe 4 comprises a contact terminal member 4A that is brought into an electric contact with an electrode pad (not shown) formed on the surface of the inspecting object and a supporting body 4B. It is possible for the contact terminal member 4A to be shaped like a pyramid, and the supporting body 4B supports the contact terminal member 4A at its tip portion (free end portion) and also acts as a lead section. It is possible for a supporting column 7 for supporting the probe 4 to be formed on the first electrode 3 of the contactor substrate 2. The supporting column 7 is formed of a conductive material such as nickel. The proximal end section of the supporting body 4B of the probe 4 is electrically connected to the supporting column 7. It is possible for the contact terminal member 4A to include a covering layer made of a conductive metal having a hardness higher than that of the electrode pad of the inspecting object. It is possible for the covering layer to be made of tungsten carbide. Whether to mount the covering layer can be determined appropriately. It is desirable for the supporting body 4B to be formed of a conductive metal such as nickel or a nickel-cobalt alloy having a spring force and a tenacity. The probe 4 is constructed such that, when the contact terminal member 4A is brought into contact with the electrode pad of the inspecting object, the contact terminal member 4A is pressed against the electrode pad by the spring force of the supporting body 4B. As a result, the contact terminal member 4A is electrically brought into contact with the electrode pad and, at the same time, the difference in height of the electrode pad is absorbed.

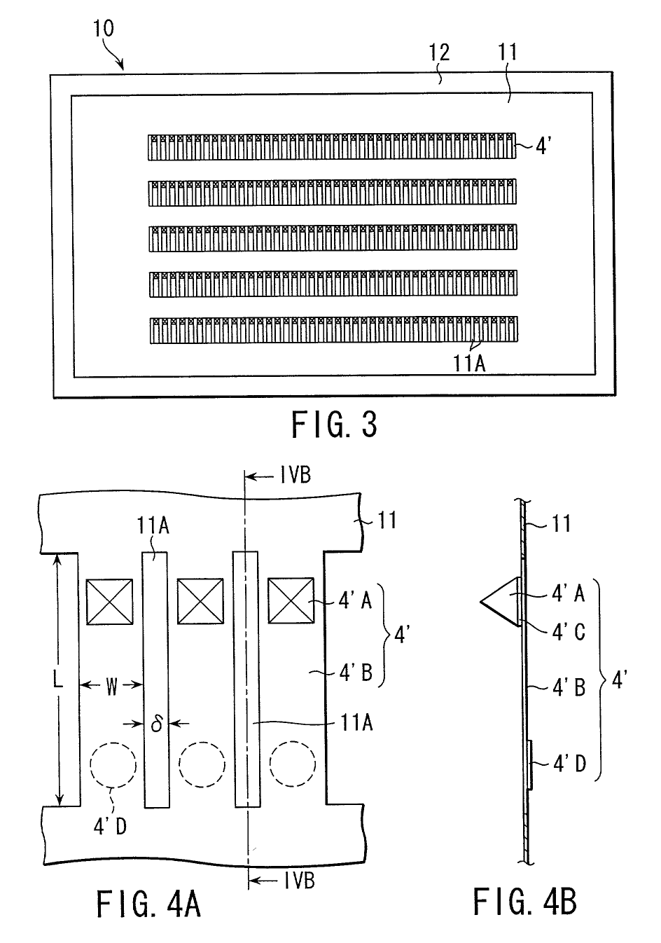

In this embodiment, a section 4′ corresponding to a plurality of probes 4, hereinafter referred to as “a probe-corresponding member”, is manufactured simultaneously by the probe arrangement assembly as shown in FIG. 3. Each probe-corresponding member 4′ of the probe arrangement assembly is mounted one by one to the contactor substrate 2 so as to form the probe 4.

The probe arrangement assembly in this embodiment and the method of manufacturing the probe arrangement assembly will now be described with reference to FIGS. 3 and 4B. In the probe arrangement assembly 10 shown in FIG. 3, the probe-corresponding members 4′ are formed in the form of a matrix on a conductive foil 11, e.g., a nickel foil. The arrangement of these probe-corresponding members 4′ is irrelevant to the arranging pattern of the probes 4 in the contactor 1. To be more specific, a large number of slits 11A each having a slit width δ of, for example, 100 μm and longer than the longer side of the probe 4 are formed in vertical and lateral directions on the nickel foil 11. The probe-corresponding member 4′ is formed between adjacent slits 11A. The probe-corresponding member 4′ comprises a section 4′A corresponding to the contact terminal member 4A, hereinafter referred to as “contact terminal-corresponding member 4′A”, and a section 4′B corresponding to the supporting body, hereinafter referred to as “supporting body-corresponding section 4′B”. It is possible for the contact terminal-corresponding member 4′A to have a bottom side of, for example, 80 μm and a height of 56 μm. On the other hand, it is possible for the supporting body-corresponding section 4′B to have a width W of, for example, 100 μm and a length L of 500 μm. The supporting body-corresponding section 4′B is formed such that the section 4′B can be separated from the nickel foil 11 at both ends in the longitudinal direction. The contact terminal-corresponding member 4′A is prepared separately from the supporting body-corresponding section 4′B and fixed to a predetermined position of the supporting body-corresponding section 4′B. Incidentally, FIG. 3 shows the state that the nickel foil 11 is mounted to a frame 12.

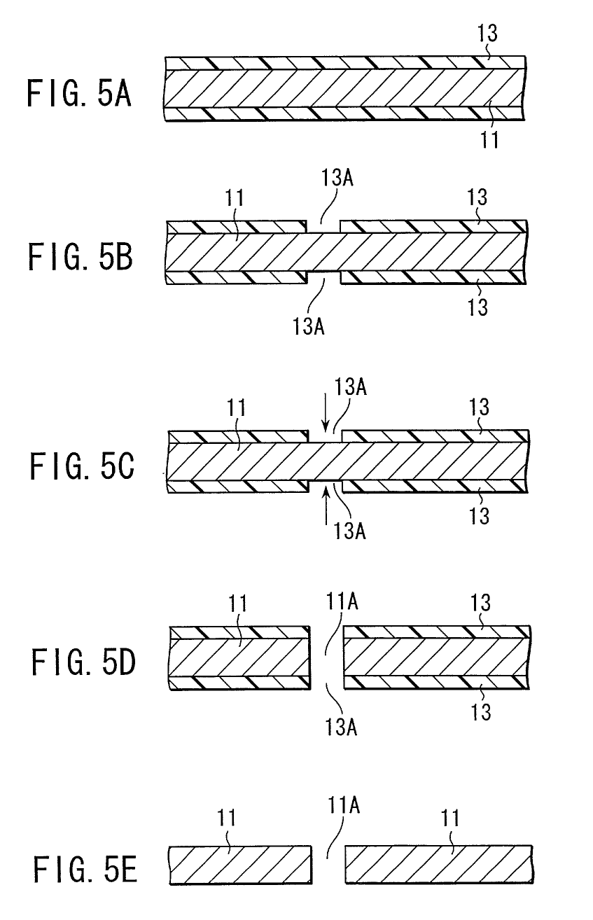

The manufacturing method of the probe arrangement assembly of this embodiment will now be described with reference to FIGS. 5A to 7. The method of manufacturing the probe arrangement assembly in this embodiment comprises the process of forming a plurality of supporting body-corresponding sections 4′B on a conductive foil 11 (nickel foil), the process of forming a plurality of contact terminal-corresponding members 4′A within the substrate to be etched, e.g., a silicon substrate, and the process of transferring the contact terminal-corresponding members 4′A formed within the silicon substrate into predetermined positions of the supporting body-corresponding sections 4′B.

The process of forming the supporting body-corresponding section will now be described with reference to FIGS. 5A to 5E. In this process, a plurality of slits 13A are formed by etching in a nickel foil 11 so as to form in a separable fashion the supporting body-corresponding section 4′B between adjacent slits 11A. In the first step, prepared is a photomask (not shown) having a light arranging pattern shown in FIG. 3. For preparing the photomask, a resist film 13 is formed on each surface of the nickel foil 11, as shown in FIG. 5A. Then, the resist films 13 on both surfaces of the nickel foil 11 are exposed to light and, then, developed so as to form openings 13A corresponding to the arranging pattern of the slits 11A, as shown in FIG. 5B. The opening 13A may be formed in only the resist film formed on one surface of the nickel foil 11. The resist film may be formed on only one surface of the nickel foil. It should be noted that the openings 13A formed on both sides of the nickel foil should overlap with each other. As shown in FIG. 5C, the nickel foil 11 is etched with an etching solution, e.g., sulfuric acid solution, through the openings 13A of the resist films 13 SO as to form a slit 11A in the nickel foil 11, as shown in FIG. 5D. In this fashion, a plurality of supporting body-corresponding sections 4′B are formed between adjacent slits 11A.

Then, a brazing agent 4′C, e.g., indium, for mounting the contact terminal-corresponding member to a predetermined position of the supporting body-corresponding section 4′B and a brazing agent 4′D, e.g., indium, for mounting the probe to the contactor substrate are formed by the printing technology or the electroplating technology, as shown in FIGS. 4A and 4B.

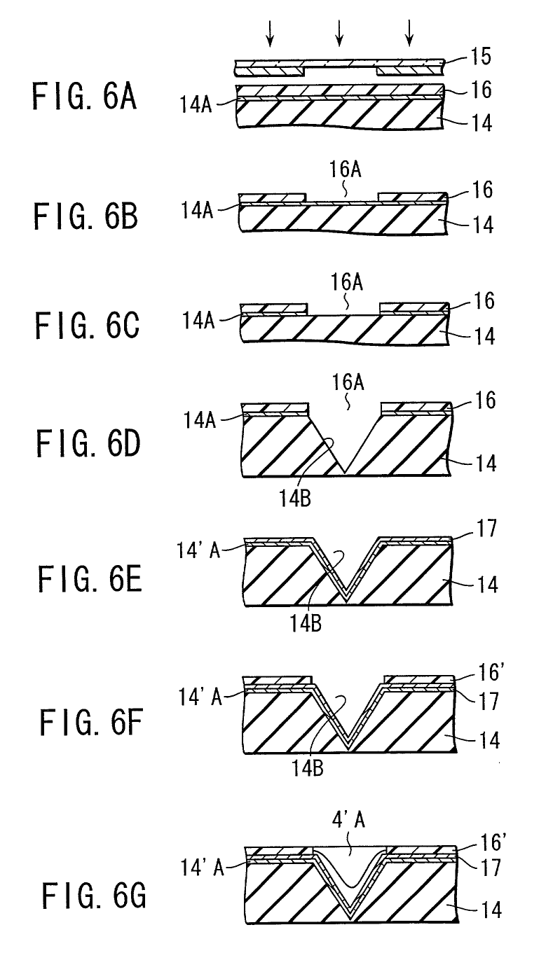

Then, the process for preparing the contact terminal-corresponding member will now be described with reference to FIGS. 6A to 6G. In this process, a plurality of contact terminal-corresponding members 4′A are formed in the substrate 14 (e.g., a silicon substrate) to be etched in conformity with the arranging pattern of the brazing agents 4′C formed in all the supporting body-corresponding sections 4′B formed in the nickel foil 11. In the first step, formed is a photomask 15 (FIG. 6A) having openings conforming with the arranging pattern of the contact terminal-corresponding members 4′A on each of the supporting body-corresponding sections 4′B. As shown in FIG. 6A, a silicon oxide film 14A is formed by thermal oxidation of the silicon substrate 14, followed by forming a resist film 16 on the thermal oxide film 14A. As shown in FIG. 6A, the resist film is exposed to light through the photomask 15, followed by development so as to form openings 16A conforming with the arranging pattern of the contact terminal-corresponding members 4′A, as shown in FIG. 6B. As shown in FIG. 6C, the silicon oxide film 14A exposed to the opening 16A is removed by etching the silicon substrate 14. As shown in FIG. 6D, a recess 14B in the form of a reversed pyramid is formed by anisotropically etching the silicon substrate 14. After the resist film 16 remaining on the surface of the silicon substrate 14 is removed, the silicon oxide film 14A is etched with an etching solution, e.g., a hydrofluoric acid solution. As shown in FIG. 6E, a silicon oxide film 14′A is formed by thermal oxidation on the surface of the silicon substrate 14. In place of newly forming the silicon oxide film 14′A, it is possible to permit the silicon oxide film 14A shown in FIG. 6D to remain as it is. Then, a titanium film 17 is formed by a sputtering method on the silicon oxide film 14′A as an electrode for an electroplating. A resist film 16′ is formed on the surface of the titanium film 17 and, then, exposed to light and developed so as to form an opening in a position corresponding to the recess 14B, as shown in FIG. 6F. As shown in FIG. 6G, for example, a tungsten carbide film is formed by a sputtering method within the recess 14B of the silicon substrate 14. Further, a nickel layer is deposited by an electroplating method on the tungsten carbide film so as to fill the recess 14B with the tungsten carbide film. Then, the resist film 16′ is removed.

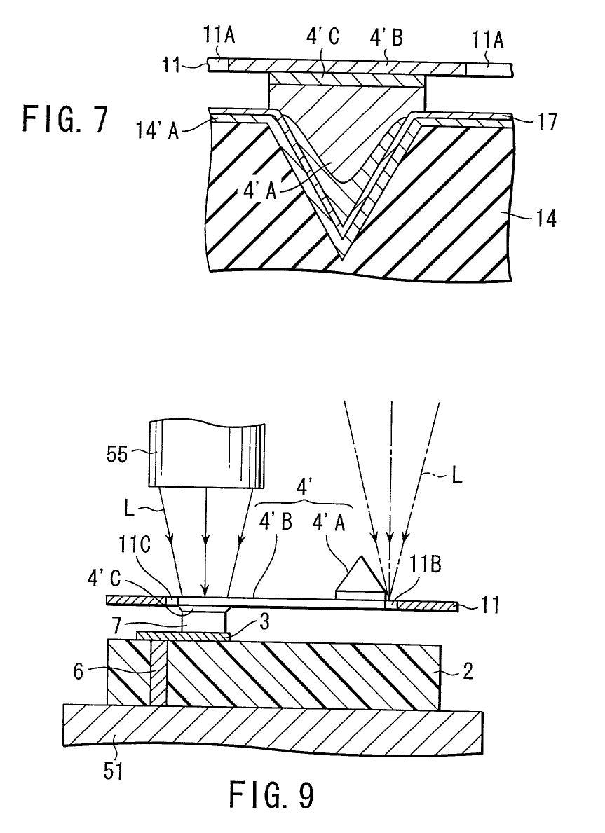

The process of transferring the contact terminal-corresponding member 4′A into the supporting body-corresponding section 4′B will now be described with reference to FIG. 7. Each of the brazing sections 4′C on the nickel foil 11 is aligned with each of the contact terminal-corresponding members 4′A of the silicon substrate 14. The contact terminal-corresponding member 4′A is bonded to the supporting body-corresponding section 4′B by means of an ultrasonic bonding method, a thermal compression bonding method, etc. The bonded structure is treated with a treating solution such as a hydrofluoric acid solution so as to dissolve the silicon oxide film 14′A on the surface of the silicon substrate 14 and the titanium film 17. As a result, the contact terminal-corresponding member 4′A is peeled off the silicon substrate 14 and, thus, the contact terminal-corresponding member 4′A is transferred onto the nickel foil 11 so as to form the probe arrangement assembly 10 having a plurality of probe-corresponding portions 4′ arranged thereon as shown in FIG. 3.

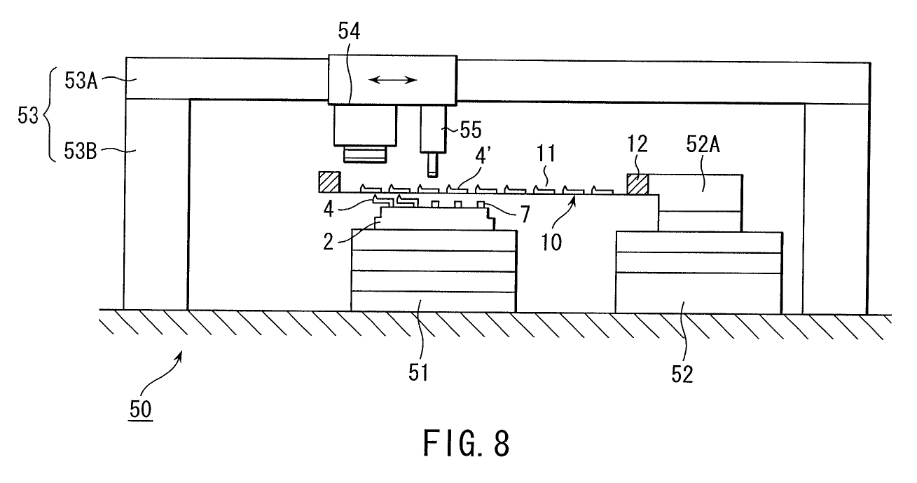

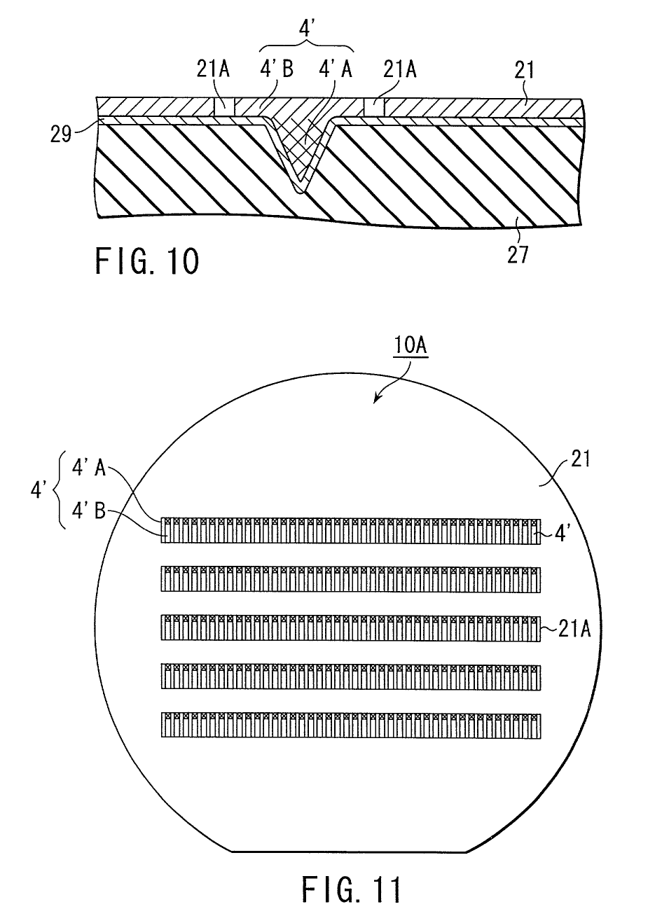

Each probe-corresponding member 4′ of the probe arrangement assembly 10 is mounted to the contactor substrate 2 by using a probe mounting apparatus shown in FIG. 8 so as to prepare a contactor. The probe mounting apparatus in this embodiment is an apparatus for fixing each probe to each conductive supporting column formed in the contactor substrate. FIG. 8 shows a probe mounting apparatus 50 used in this embodiment. As shown in the drawing, the probe mounting apparatus 50 comprises a work table 51 having the contactor substrate 2 mounted thereon, a supporting body 52 supporting the probe arrangement assembly 10, a frame 53 surrounding the work table 51 and the supporting body 52, and an alignment mechanism mounted to the frame 53. The alignment mechanism may comprise a CCD camera 54 housing a zoom mechanism.

The work table 51 having the contactor substrate 2 provided with a plurality of supporting columns 7 mounted thereon can be moved in X, Y, Z and θ directions. The supporting body 52 supporting via a supporting member 52A the probe arrangement assembly 10 in a predetermined direction in parallel with the contactor substrate 2 may be moved in X, Y and Z directions. The frame 53 comprises a horizontal frame 53A formed in the shape of a frame and a supporting column 53B supporting the horizontal frame 53A. The horizontal frame 53A is mounted to permit the CCD camera 54 and a laser processing machine 55 to be moved in the left-right direction via a guide rail (not shown). If the work table 51 is moved to a position right below the CCD camera 54, the CCD camera 54 picks up the image of the supporting column 7 of the contactor substrate 2. The work table 51 is moved in X, Y, Z and θ directions so as to permit the contactor substrate 2 to be aligned with the direction of the probe-corresponding member 4′ of the probe arrangement assembly 10. The CCD camera 54 picks up the image of the supporting column 7 of the contactor substrate 2 so as to recognize the coordinates (XO, YO, ZO) of the position. The frame body 12 permits the probe arrangement assembly 10 to be kept supported by the supporting body 52 in a predetermined direction. If the supporting body 52 is moved to a position right under the CCD camera 54, the CCD camera picks up the image of the proximal end of the probe-corresponding member 4′ providing the reference point of the probe arrangement assembly 10 so as to recognize the coordinates (X0, YO, ZO) of the position. Then, the distance in the Z-direction between the supporting column 7 providing the reference point and the brazing section 4′C is calculated. The data on the position information of each supporting column 7 of the contactor substrate 2 is stored in advance. Since the brazing sections 4′C of the probe arrangement assembly 10 are arranged at a predetermined interval, all the supporting columns 7 can be aligned with the brazing sections 4′C by moving the work table 51 and the supporting body 52 by a predetermined distance in X, Y, and Z directions successively.

The laser processing machine 55 is mounted to the horizontal frame 53A in a manner to be movable in the left-right direction. The laser processing machine 55 serves to bond the supporting column 7 to the brazing section 4′C of the probe arrangement assembly 10 and permits the probe-corresponding member 4′ to be separated from the probe arrangement assembly 10 and to be mounted to the contactor substrate 2. The process for the laser processing machine 55 to permit the probe-corresponding member 4′ to be bonded to the supporting column 7 will now be described. As denoted by a solid line in FIG. 9, the laser processing machine 55 permits the probe-corresponding member 4′ to be bonded to the supporting column 7 under the state that the focus of the laser light L is positioned below the probe-corresponding member 4′. As a result, it is possible to avoid the melting of the nickel foil 11 caused by the laser light L. When the probe-corresponding member 4′ is separated from the nickel foil 11, the focus of the laser light L is on edge portions 11B and 11C of the probe-corresponding member 4′, as denoted by a dot-and-dash line. When the probe-corresponding member 4′ is separated from the probe arrangement assembly 10, it is possible for the work table 51 and the supporting body 52 to be moved in synchronism. Alternatively, the laser processing machine 55 alone may be moved.

The probe mounting method using a probe mounting apparatus in this embodiment will now be described. In the first step, the contactor substrate 2 is mounted on the work table 51, and the probe arrangement assembly 10 is mounted to the supporting member 52A of the supporting body 52. Then, the CCD camera 54 is moved to a predetermined position so as to pick up the image of the supporting column 7 of the contactor substrate 2 mounted on the work table 51. Also, the work table 51 is moved in X, Y, Z and θ directions to permit the direction of the contactor substrate 2 to be aligned with the mounting direction of the probe 4 so as to recognize the reference position of the supporting column 7. Further, the supporting body 52 is moved in x and Y directions so as to move the probe arrangement assembly to a position above the contactor substrate 2. An image of the reference probe-corresponding member 4′ of the probe arrangement assembly 10 is picked up by the CCD camera 54 so as to calculate the distance in the Z direction between the brazing section 4′C and the reference supporting column 7.

The CCD camera 54 is moved, and the laser processing machine 55 is moved to a position of the CCD camera 54. The work table 51 and the supporting body 52 are moved in the Z direction to the position of the laser processing machine 55 denoted by a solid line in FIG. 9. As a result, the supporting column 7 is brought into contact with the brazing section 4′C and the focus of the laser processing machine 55 is positioned below the brazing position 4′C. Under this condition, the brazing section 4′C is irradiated with pulse of laser light L emitted from the laser processing machine 55 so as to permit the supporting body-corresponding section 4′B to be bonded to the supporting column 7 via the brazing section 4′C. As denoted by a dot-and-dash line in FIG. 9, the work table 51 and the supporting body 52 are moved in the X, Y, Z directions so as to permit the focus of the laser light L to be positioned on both edge portions of the supporting body-corresponding section 4′B. The laser light L is emitted from the laser processing machine 55, and the work table 51 and the supporting body 52 are moved by a distance conforming with the width of the supporting body-corresponding section 4′B. One edge portion 11B of the supporting body-corresponding section 4′B is cut off. The other edge portion 11C of the supporting body-corresponding section 4′B is also cut off, and the supporting body-corresponding section 4′B is mounted as the probe 4 to the supporting column 7 of the contactor substrate 2. The operation described above is repeated so as to mount the probe 4 to all the supporting columns 7 of the contactor substrate 2.

As described above, according to this embodiment, the nickel foil 11 is provided with a plurality of slits 11A and the supporting body-corresponding section 4′B is formed between adjacent slits 11A. The both edges of the supporting body-corresponding section 4′B are cut off so as to permit the supporting body-corresponding section 4′B to be separable from the nickel foil 11. A plurality of contact terminal-corresponding members 4′A are formed in the substrate 14 to be etched, e.g., a silicon substrate, to form an arrangement conforming with the positions in one edge portion of each of the supporting body-corresponding sections 4′B formed in the nickel foil 11. The contact terminal-corresponding members 4′A formed in the silicon substrate 14 are transferred onto the supporting body-corresponding sections 4′B formed in the nickel foil 11. The present invention comprising the processes described above makes it unnecessary to prepare a photomask exclusively for use for the probe for every contactor as in the prior art. The present invention makes it possible to manufacture simultaneously the probes 4, which can be commonly used in the contactor 1, in large amounts in the probe arrangement assembly 10 made of a nickel foil differing from the contactor 1.

In this embodiment, each probe-corresponding member 4′ of the probe arrangement assembly 10 can be automatically mounted to the supporting column 7 of the contactor substrate 2 by using the probe mounting apparatus 50. According to the present invention, a small amount of various kinds of the contactors 1 having different probe arranging patterns can be manufactured by preparing in advance a large amount of a single kind of probe assemblies 10. According to the present invention, it is possible to manufacture the contactor 1 and the probe card at a low cost without requiring the photomask used exclusively for the probe for every contactor 1.

FIG. 10 shows a method of manufacturing probes according to another embodiment of the present invention. As shown in FIG. 10, the probe manufacturing method in this embodiment comprises the process of arranging in a matrix form a plurality of contact terminal-corresponding members 4′ in the substrate 27 to be etched, e.g., a wafer, the process of forming a nickel foil layer 21 on the wafer 27 by means of, for example, an electroplating, the process of arranging in a matrix form slits 21A in the nickel foil layer 21, a supporting body-corresponding section 4′B being formed between adjacent slits 21A and both edges of each of said supporting body-corresponding section 4′B being cut off so as to make the supporting body-corresponding section 4′B separable from the nickel foil layer, and the process of peeling the wafer 27 from the nickel foil layer 21 having the contact terminal-corresponding member 4′A formed therein so as to manufacture the probe arrangement assembly 10A as shown in FIG. 11. A reference numeral 29 shown in FIG. 10 represents a titanium film.

In the process of preparing the contact terminal-corresponding member 4′A, the contact terminal-corresponding members 4′A are arranged in conformity with the arranged state of a plurality of probe-corresponding members 4′. In this process, it is possible to take the procedures similar to those shown in FIG. 6. In the process of forming the nickel foil layer 21, nickel is plated on the surface of the wafer 27 so as to form the nickel foil layer in a thickness of, for example, about 15 μm. In the process of forming the supporting body-corresponding section 4′B, a resist film (not shown) is formed first on the surface of the nickel foil layer 21, followed by selectively exposing the resist film to light, followed by development so as to form openings corresponding to the arranging pattern of the slits 21A in the resist film. Then, the nickel foil layer 21 exposed to the opening of the resist film is etched so as to form the slit 21A in the nickel foil layer 21. The wafer 27 is treated with, for example, a hydrofluoric acid solution so as to permit the nickel foil layer 21 to be peeled off the wafer 27, thereby obtaining the probe arrangement assembly 10A shown in FIG. 11. It is possible to form brazing sections (not shown) in predetermined positions on both surfaces of the probe arrangement assembly 10A as in the embodiment described previously. Each probe is mounted to the contactor substrate as shown in FIG. 9 by using the probe mounting apparatus 50 shown in FIG. 8. The function and effect similar to those produced in the embodiment described previously can also be produced in this embodiment, too.

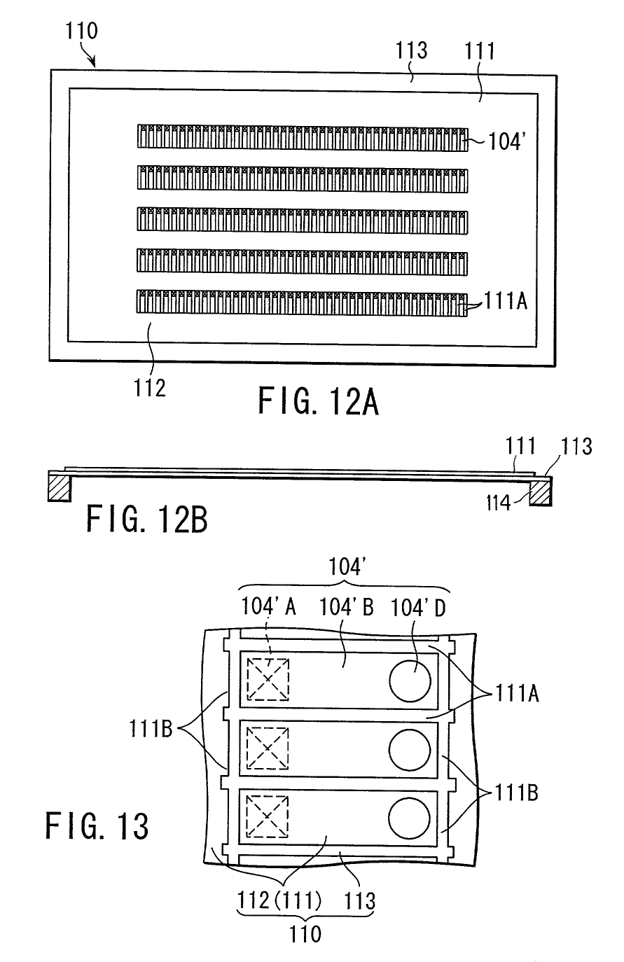

FIG. 12A shows a probe arrangement assembly 110 according to another embodiment of the present invention. FIG. 12B is a cross sectional view of the probe arrangement assembly shown in FIG. 12A. The probe arrangement assembly 110 in this embodiment may be constructed like the probe arrangement assembly 10 shown in FIGS. 3, 4A and 4B except the portion described below. The probe arrangement assembly 110 in this embodiment comprises a probe arrangement assembly foil 112 having a plurality of probe-corresponding members 104′ formed therein and a sheet substrate 113, e.g., a resin sheet made of vinyl chloride series resin, tetrafluoroethylene series resin, etc., bonded to the probe arrangement assembly foil 112. It is desirable for the sheet substrate 113 bonded to the probe arrangement assembly foil 112 to be stretched over a frame body 114, as shown in FIG. 12B. AS shown in FIG. 13, the probe-corresponding member 104′ is in the state of being separated from the nickel foil 111 and is peelable from the sheet substrate 113. Like the probe arrangement assembly 10, the probe arrangement assembly 110 is attached to the frame body for use.

In this embodiment, the probe-corresponding member 104′ is formed in the nickel foil 111. In this stage, the probe-corresponding member 104′ is formed integral with the nickel foil 111 as in FIGS. 4A and 4B. The nickel foil 111 is bonded to the sheet substrate 113 with an adhesive interposed therebetween so as to manufacture the probe arrangement assembly 110. It is possible to coat in advance at least one of the nickel foil 111 and the sheet substrate 113 with the adhesive. The coated adhesive is irradiated in advance with, for example, an ultraviolet light so as to lower the adhesion force. As a result, it is possible for any one of the nickel foil 111 and the sheet substrate 113 to be peeled easily off the other. After the probe arrangement assembly 110 is prepared in this fashion, slits 111B for cutting the both edge portions of the slit 111A, i.e., the both edge portions of the supporting body-corresponding sections 104′B, are formed using, for example, an excimer laser processing machine. As shown in FIG. 13, the probe-corresponding member 104′ is surrounded by the slits 111A and 111B so as to be separated from the nickel foil 111. Since the probe-corresponding member 104′ can be peeled easily from the sheet substrate 113 because of the series of treatments described above, the operation for cutting the probe-corresponding member 104′ from the nickel foil 111 need not be performed every time the probe is mounted to the contactor substrate. It is possible to simplify the construction of the probe mounting apparatus and the time required for the probe mounting operation can be shortened. Incidentally, a reference numeral 104′A shown in FIG. 13 denotes the contact terminal-corresponding member, with a reference numeral 104′D denoting a brazing section.

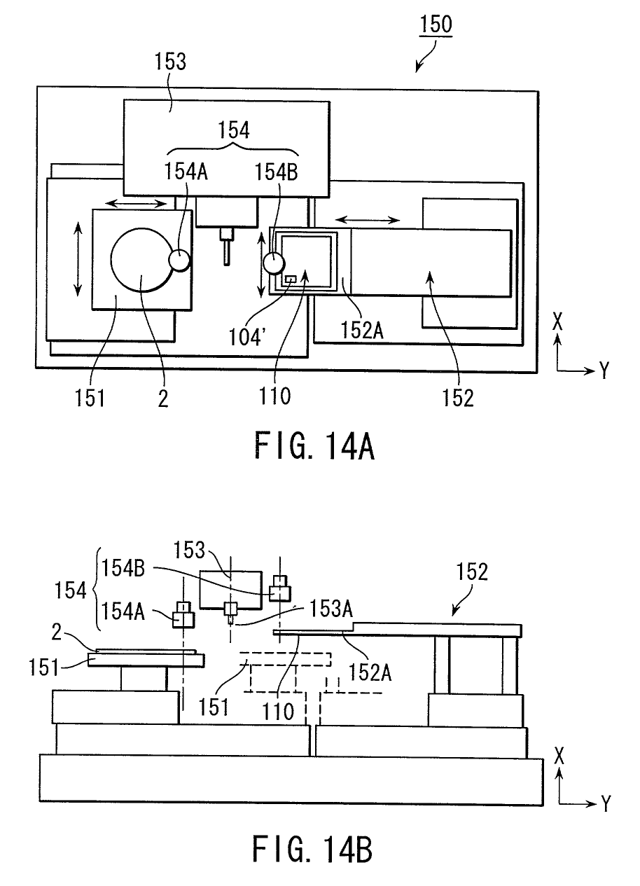

Each probe-corresponding member 104′ of the probe arrangement assembly 110 is mounted to the contactor substrate 2 by using a probe mounting apparatus 150 shown in FIGS. 14A and 14B so as to manufacture the contactor. As shown in FIGS. 14A and 14B, the probe mounting apparatus 150 comprises a work table 151 having the contactor substrate 2 mounted thereon and movable in the X, Y, Z and θ directions, a supporting body 152 supporting the probe arrangement assembly 110 via a supporting section 152A and movable in the X, Y and Z directions, a bonder 153 for bonding the probe-corresponding member 104′ of the probe arrangement assembly 110 to the contactor substrate 2 by utilizing an ultrasonic wave, and an alignment mechanism 154 consisting essentially of CCD cameras 154A, 154B each housing a zooming function for aligning the contactor substrate 2 with the probe arrangement assembly 110. The coordinates of the positions to which the bonder 153 and the CCD cameras 154A, 154B are fixed are related to each other. To be more specific, the optical axis of the CCD camera 154A or the optical axis of the CCD camera 154B is positioned a predetermined distance apart from the bonding position of the bonder 153. If the CCD camera 154A is aligned with a predetermined point of the contactor substrate 2, the moving amount between the predetermined point noted above and the bonding point of the bonder 153 is rendered constant (value inherent in X and Y directions). A similar relationship is established among the CCD camera 154B, the bonder 153 and the CCD camera 154A.

The probe mounting method using the probe mounting apparatus 150 in this embodiment will now be described. Specifically, the contactor substrate 2 is mounted in the first step on the work table 151. Then, the work table 151 is moved in the X, Y, Z and θ directions so as to align the contactor substrate 2. After the probe arrangement assembly 110 is mounted to the supporting section 152A of the supporting body 152, the supporting body 152 is moved in the X and Y directions so as to align the probe arrangement assembly 110. Then, the work table 151 is moved by a predetermined distance in the X and Y directions so as to move the supporting column 7 to a position below the CCD camera 154A. Where the supporting column 7 does not coincide with the optical axis of the CCD camera 154A in this step, the position is corrected to permit the center of the supporting column 7 to be aligned with the optical axis of the CCD camera 154A. Then, the supporting body 152 is moved in the X and Y directions by a predetermined amount relative to the probe-corresponding member 104′ of the probe arrangement assembly 110 to be bonded so as to move the brazing section 104′D of the probe-corresponding member 104′ to a position below the CCD camera 154B. Where the brazing section 104′D does not coincide with the optical axis of the CCD camera 154B, the position is corrected to permit the center of the brazing section 104′D to be aligned with the optical axis of the CCD camera 154B. If an article defective in the shape of, for example, the probe-corresponding portion 104′ has been found, the defective probe-corresponding member 104′ is not used, and the particular article is skipped to permit the next probe-corresponding member 104′ to be moved to reach a position right under the CCD camera 154B.

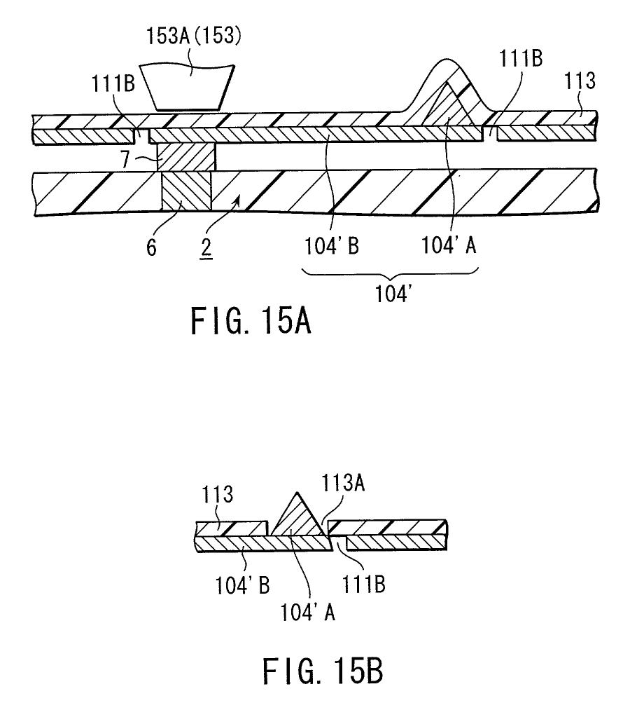

Then, the work table 151 and the supporting body 152 are moved in the X and Y directions by distances inherent in these work table 151 and supporting body 152 so as to permit the supporting column 7 of the contactor substrate 2 and the brazing section 104′D of the probe-corresponding member 104′ to be moved to positions right under the bonder 153. Further, the work table 151 is moved upward in the Z direction by a predetermined distance (value inherent in the direction Z) so as to bring the supporting column 7 into contact with the brazing section 104′D of the probe-corresponding member 104′, as shown in FIG. 15A. Then, a ultrasonic wave head 153A of the bonder 153 is moved downward so as to be brought into contact with the probe-corresponding member 104′, with the result that the supporting column 7 is bonded to the probe-corresponding member 104′ by the ultrasonic wave. Further, the work table 151 is moved down to the original position, and the probe 104 is peeled off the sheet substrate 113 of the probe arrangement assembly 110, thereby finishing the mounting operation of the probe 104 to the contactor substrate 2. It is possible to carry out the operation between the alignment of the supporting column 7 with the probe-corresponding member 104′ of the probe arrangement assembly 110 and the bonding of these supporting column 7 and the probe-corresponding member 104′ in a cycle within, for example, 3 seconds. FIG. 15B is a cross sectional view showing a gist portion of the sheet substrate 113 provided with the opening 113A corresponding to the contact terminal-corresponding member 104′A.

In each of the embodiments of the present invention described above, the slits 11A, 21A and 111A are formed parallel to each other in the probe assemblies 10, 10A and 110, respectively. However, it is possible to change appropriately the arrangement of the slits 11A, 21A and 111A in accordance with the planar shape of the supporting body 4B. In each of these embodiments described above, the slits are formed by etching. However, it is also possible to form the slits by another method, e.g., by a laser processing. Also, in each of the embodiments described above, the probe-corresponding member 4′ is joined to the nickel foil 11 over the entire width of the probe-corresponding member 4′. However, it is also possible for a part of the entire width of the probe-corresponding member to be joined to the nickel foil. In this case, it is possible to allow an overcurrent to flow through the joining section so as to burn out the joining section. Also, in each of the embodiments described above, the contact terminal-corresponding member 4′A is shaped pyramidal. However, the shape of the section 4′A may be changed appropriately. Also, the contactor substrate is shaped substantially circular in each of the embodiments described above. However, the shape of the contactor substrate 2 may be changed appropriately. Also, the probes 4 are arranged to form a matrix on the contactor substrate 2 in each of the embodiments described above. However, the arrangement of the probes 4 can be changed appropriately depending on the object to be inspected. Further, a silicon substrate is etched for preparing the contact terminal member in each of the embodiments described above. However, the substrate to be etched is not limited to a silicon substrate. It is possible to use various other substrates such as other semiconductor substrates for preparing the contact terminal member.

Each of the embodiments of the present invention described above is directed to the manufacture of a new probe card by using the probe assemblies 10, 10A or 110. However, it is also possible to repair the damaged probes in a probe card by using the probe assemblies 10, 10A, 110 and the probe mounting apparatuses 50, 150 used in each of the embodiments described previously.

The present invention provides a manufacturing method capable of mass production of probes that can be commonly employed for contactors differing from each other in the arranging pattern of the probes.

According to the present invention, it is unnecessary to use a photomask for preparing various kinds of probes in a small amount. Since a single kind of probe can be employed for a probe card of a different kind, the present invention provides a probe mounting method and a probe mounting apparatus capable of manufacturing a probe card with a low manufacturing cost.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A probe arrangement assembly used for forming probes, each probe having a supporting body and a contact terminal member fixed to one end of said supporting body, comprising:
a conductive foil having a plurality of sections corresponding to said supporting bodies formed integral with said foil, each of said supporting body-corresponding sections being separable from said conductive foil; and
contact terminal-corresponding members corresponding to said contact terminal members, each of said members being fixed to one end of each of said supporting body-corresponding sections.

2. The probe arrangement assembly according to claim 1, wherein each of the supporting body-corresponding sections is made separable from the conductive foil by cutting away the supporting body-corresponding sections from the conductive foil except at least a part of the circumferential edge.

3. The probe arrangement assembly according to claim 1, wherein at least the tip surface of the contact terminal-corresponding member is made of a conductive material having a hardness higher than that of the inspecting electrode of the inspecting object.

4. The probe arrangement assembly according to claim 1, wherein at least the tip portion of the contact terminal-corresponding member is covered with tungsten carbide.

5. The probe arrangement assembly according to claim 1, wherein the contact terminal-corresponding member is made of at least one material selected from nickel and a nickel alloy, the tip surface of the contact terminal-corresponding member is covered with tungsten carbide, and the conductive foil is formed of a metal having a spring force.

6. The probe arrangement assembly according to claim 1, wherein, in order to make each of the supporting body-corresponding sections separable from the conductive foil, a sheet substrate is bonded to the conductive foil and the peripheral edges of a plurality of supporting body-corresponding sections formed integral with the conductive foil are separated from the conductive foil by slits.

7. A method of manufacturing a probe arrangement assembly used for preparation of a probe having a supporting body formed of a conductive foil and a contact terminal-corresponding member fixed to one end of said supporting body, comprising the steps of:
forming a plurality of supporting body-corresponding sections in a conductive foil, said supporting body-corresponding sections being formed separable from said conductive foil;
forming a plurality of contact terminal-corresponding members within a substrate to be etched such that the bottom surface of said contact terminal-corresponding member faces outside the substrate to be etched, said plural contact terminal-corresponding members being arranged to conform with the positions to which said contact terminal-corresponding members are fixed in each supporting body-corresponding section formed in said conductive foil; and
collectively transferring contact terminal-corresponding members formed in the substrate to be etched into the positions to which the contact terminal-corresponding members are fixed in a plurality of supporting body-corresponding sections formed in the conductive foil.

8. The method of manufacturing a probe arrangement assembly according to claim 7, wherein the substrate to be etched is a silicon substrate, and each supporting body-corresponding section is formed separable from the conductive foil by allowing the slits to separate each supporting body-corresponding section from the conductive foil except at least one edge portion.

9. The method of manufacturing a probe arrangement assembly according to claim 7, wherein the step of forming a plurality of supporting body-corresponding sections in said conductive foil comprises the sub-steps of:
forming a resist film on at least one surface of said conductive foil;
forming an opening corresponding to said slit in said resist film; and
etching the conductive foil exposed to said opening so as to form the slit in said conductive foil.

10. The method of manufacturing a probe arrangement assembly according to claim 7, wherein the step of forming a plurality of contact terminal-corresponding members within a silicon substrate comprises the sub-steps of:
forming a resist film on said substrate to be etched;
forming openings in said resist film in positions and sizes in which said contact terminal-corresponding members are to be arranged;
etching said substrate through said openings so as to form a plurality of recesses of a predetermined shape within the substrate to be etched; and
filling a conductive material in said recesses.

11. The method of manufacturing a probe arrangement assembly according to claim 7, wherein a sheet substrate is bonded to said conductive foil and the peripheral edges of a plurality of said supporting body-corresponding sections formed integral within said conductive foil are separated from said conductive foil by slits so as to make said supporting body-corresponding sections separable from said conductive foil.

12. A method of manufacturing a probe arrangement assembly used for formation of a probe having a supporting section formed of a conductive foil and a contact terminal-corresponding member fixed to one end of said supporting body, comprising the steps of:
forming a plurality of contact terminal members within a substrate to be etched such that the bottom surface of the contact terminal member faces outward;
forming a conductive layer on said substrate to be etched, the bottom surfaces of said plural contact terminal-corresponding members being integrally fixed to each other by said conductive layer;
forming a plurality of slits in said conductive layer so as to form sections corresponding to said plural supporting bodies, the sections corresponding to these supporting bodies including portions to which said contact terminal-corresponding members are fixed and being formed separable from said conductive layer; and
peeling said conductive layer, in which the sections corresponding to said plural supporting bodies are formed, from the substrate to be etched.

13. The method of manufacturing a probe arrangement assembly according to claim 12, wherein the substrate to be etched is a silicon substrate and the sections corresponding to said plural supporting bodies, which are separated from said conductive layer by said slits except at least a part of the peripheral edge, are formed separable from said conductive layer.

14. The method of manufacturing a probe arrangement assembly according to claim 13, wherein the step of forming said contact terminal-corresponding members within said silicon substrate comprises the sub-steps of:
forming a resist film on said silicon substrate;
forming in said resist film openings corresponding to the arrangement and sizes of the sections corresponding to said contact terminal-corresponding members;
etching said silicon substrate through the openings of said resist film so as to form recesses in said silicon substrate; and
filling a conductive material for the contact terminal-corresponding member in said recess.

15. The method of manufacturing a probe arrangement assembly according to claim 13, wherein the step of forming a section corresponding to a plurality of said supporting bodies in the conductive layer comprises the sub-steps of:
forming a resist film on the surface of said conductive film;
forming in said resist film openings corresponding to the arrangement and sizes of said slits; and
etching said conductive film through the opening of said resist film so as to form said slit in said conductive layer.

16. The method of manufacturing a probe arrangement assembly according to claim 13, wherein the step of forming a conductive layer on said silicon substrate is a plating step.

17. The method of manufacturing a probe arrangement assembly according to claim 13, wherein the conductive layer is formed of a conductive metal having a spring force.

18. The method of manufacturing a probe arrangement assembly according to claim 13, wherein at least the tip surface of said contact terminal-corresponding member is covered with a metal layer having a hardness higher than that of said inspecting electrode and excellent in conductivity.

19. The method of manufacturing a probe arrangement assembly according to claim 12, wherein a sheet substrate is bonded to said conductive foil and the peripheral edges of a plurality of said supporting body-corresponding sections formed integral with said conductive foil are separated from said conductive foil by slits so as to make said supporting body-corresponding sections separable from said conductive foil.

20. A method of mounting a plurality of probes to a contactor substrate by using a probe arrangement assembly used for forming a probe having a plurality of supporting bodies each formed of a conductive foil and contact terminal-corresponding members each fixed to one end of each of said supporting bodies, comprising the steps of:
aligning the contactor substrate, which is mounted on a work table, with said probe arrangement assembly;
fixing one of a plurality of supporting body-corresponding sections within said probe arrangement assembly to said contactor substrate; and
separating said fixed supporting body-corresponding section from said probe arrangement assembly.

21. The method of mounting a plurality of probes to a contactor substrate according to claim 20, wherein the step of separating said fixed supporting body-corresponding section from said probe arrangement assembly comprises separating said supporting body-corresponding section from the conductive foil of said probe arrangement assembly.

22. An apparatus for mounting a plurality of probes to a contactor substrate by using a probe arrangement assembly used for forming a probe having a plurality of supporting bodies each formed of a conductive foil and contact terminal-corresponding members each fixed to one end of each of said supporting bodies, comprising:
a work table having the contractor substrate mounted thereon and movable in X, Y, Z and θ directions;
a supporting body supporting said probe arrangement assembly and movable in at least X and Y directions;
a mechanism for aligning the positions of said contactor substrate and said probe arrangement assembly by moving at least one of said work table and said supporting body;
a mechanism for fixing one of a plurality of supporting body-corresponding sections of said probe arrangement assembly to said contactor substrate; and
a mechanism for separating said fixed supporting body-corresponding section from said probe arrangement assembly.

23. The apparatus for mounting a probe to a contactor substrate according to claim 22, wherein the mechanism for separating the fixed supporting body-corresponding section from said probe arrangement assembly includes a mechanism for cutting off the peripheral edge of the supporting body-corresponding section from the conductive foil of said probe arrangement assembly.
